(19) United States
(12) Patent Application Publication
(10) Pub. No.: US 2026/0221375 A1
(43) Pub. Date: Jul. 30, 2026

(54) OBJECTIVE LENS COOLING SYSTEM

(71) Applicant: ASML Netherlands B.V., Veldhoven (NL)

(72) Inventors: Paul CASUCCI, Scotts Valley, CA (US); Xiaoyu JI, San Jose, CA (US); Le YU, San Jose, CA (US); Xingtian TAO, San Jose, CA (US)

(73) Assignee: ASML Netherlands B.V., Veldhoven (NL)

(21) Appl. No.: 19/143,982

(22) PCT Filed: Dec. 13, 2023
(86) PCT No.: PCT/EP2023/085458

§ 371 Date: Jun. 27, 2025

Related U.S. Application Data
(60) Provisional application No. 63/435,771, filed on Dec. 28, 2022.

(51) Int. Cl. H01J 37/141; H01J 37/28

(52) U.S. Cl. CPC H01J 37/141; H01J 37/28; H01J 2237/002; H01J 2237/1405

(57) ABSTRACT

An improved magnetic lens cooling system is disclosed. A magnetic lens assembly can comprise a coil, a housing containing the coil, and a pole piece that is isolated from the housing such that there is a gap between the housing and the pole piece. Wherein the magnetic lens assembly can be configured to have a vacuum pressure in the gap.

### CROSS-REFERENCE TO RELATED APPLICATIONS

This application claims priority of U.S. application 63/435,771 which was filed on Dec. 28, 2022 and which is incorporated herein in its entirety by reference.

### TECHNICAL FIELD

The embodiments provided herein disclose an objective lens assembly, and more particularly objective lens cooling system to, for example, minimize thermal deformation of the objective lens assembly in an inspection apparatus.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, defect detection accuracy becomes more important. Accordingly, precise control of charged particle beams to targeted positions on a sample has become critical to meet the higher demand for accurate inspection and metrology.

### SUMMARY

Some embodiments provide a charged-particle beam inspection apparatus comprising a charged-particle beam source configured to generate a primary charged-particle beam for sample scanning and an objective lens assembly configured to influence the charged particle beam. The objective lens assembly can comprise: a coil, a housing containing the coil, and a pole piece that is isolated from the housing such that there is a gap between the housing and the pole piece. Wherein the objective lens assembly can be configured to have a vacuum pressure in the gap.

Some embodiments provide a magnetic lens assembly. The magnetic lens assembly can comprise a coil, a housing containing the coil, and a pole piece that is isolated from the housing such that there is a gap between the housing and the pole piece. wherein the magnetic lens assembly is configured to have a vacuum pressure in the gap.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an exemplary charged-particle beam inspection system, consistent with embodiments of the present disclosure.

FIG. 2A is a schematic diagram illustrating an exemplary multi-beam tool, consistent with embodiments of the present disclosure that can be a part of the exemplary charged-particle beam inspection system of FIG. 1.

FIG. 2B is a schematic diagram illustrating an exemplary single-beam tool, consistent with embodiments of the present disclosure that can be a part of the exemplary charged-particle beam inspection system of FIG. 1.

FIG. 3 is a cross-section view of a conventional magnetic lens assembly.

FIG. 4 is a cross-section view of an exemplary magnetic lens assembly, consistent with embodiments of the present disclosure.

FIG. 5A is a schematic diagram illustrating an exemplary fluid channel formed in a housing of a magnetic lens assembly of FIG. 4, consistent with embodiments of the present disclosure.

FIG. 5B is a schematic diagram illustrating an exemplary housing of a magnetic lens assembly of FIG. 4, consistent with embodiments of the present disclosure.

FIG. 6A is a schematic diagram illustrating an exemplary coupling structure in a magnetic lens assembly of FIG. 4, consistent with embodiments of the present disclosure.

FIG. 6B is a schematic diagram illustrating an exemplary pipe in a magnetic lens assembly of FIG. 4, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. For example, although some embodiments are described in the context of utilizing electron beams, the disclosure is not so limited. Other types of charged-particle beams (e.g., including protons, ions, muons, or any other particle carrying electric charges) may be similarly applied. Furthermore, other imaging systems may be used, such as optical imaging, photon detection, x-ray detection, ion detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000 th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

As the physical sizes of IC components continue to shrink, defect detection accuracy becomes more important. Accordingly, precise control of charged particle beams to targeted positions on a sample has become critical to meet the higher demand for accurate inspection and metrology. In a charged-particle beam imaging or inspection system, such as a SCPM, the charged-particle beam may be focused on the wafer using an electromagnetic lens having electromagnetic coils (e.g., the coils being inside a ferromagnetic base). An electric current through the electromagnetic coils may generate a magnetic field that focuses or defocuses the charged-particle beam. The amount of heat generated may be proportional to the electric current passing through the coils and to the number of coils. In a conventional magnetic lens assembly, a pole piece of the electromagnetic lens assembly is not thermally isolated from a heat source, e.g., coils of the electromagnetic lens assembly. For example, heat generated by coils can be transmitted to a pole piece via heat convection using air between the pole piece and the coils as a heat transmission medium. Thereby, heat generated by coils can be transferred to the pole piece. However, a slight temperature change of the pole piece can cause the pole piece to thermally expand or physically deform. Such thermal expansion and dimensional deformation of the pole piece can make magnetic field guidance by the pole piece unstable, while in turn making it challenging to place precisely focused charged particle beams onto targeted positions on a sample, thereby making it challenging to acquire accurate inspection images. Accordingly, a cooling mechanism that can minimize heat transmission to a pole piece while efficiently cooling down coils is desired. Thermal management issues may be accentuated in a multi-beam inspection tool. Though useful in increasing the wafer inspection throughput by using multiple beams to inspect a wafer, where each beam may image a different point on the wafer, multi-beam inspection tools may be plagued by excessive heat generation. Focusing multiple beams may require a larger number of electromagnetic coils or higher electric current to be passed through the electromagnetic coils, necessitating improved heat dissipation systems and methods.

Embodiments of the present disclosure can provide a magnetic lens assembly that can minimize heat transmission to a pole piece from a coil. According to some embodiments of the present disclosure, a pole piece can be thermally isolated from a heat source, e.g., a coil of a magnetic lens assembly. In some embodiments, a magnetic lens assembly can be configured to have a gap between a pole piece and a housing containing a coil, and the gap is maintained under a vacuum. Because the gap between a pole piece and a housing containing a coil is under a vacuum condition, heat transmission from the coil to the pole piece via heat convection can be minimized. Resultantly, the amount of heat transferred to the pole piece from the coil can be reduced according to some embodiments of the present disclosure. While a magnetic lens assembly can be configured to eliminate one heat dissipation path (e.g., heat convection via air) from a coil in some embodiments, it will be appreciated that heat dissipation efficiency from the coil may not be affected by the loss of the heat dissipation path. In some embodiments, heat from the coil is concentrated into a cooling fluid circulating the housing containing the coil. As a result, heat dissipation efficiency may not be degraded by the loss of the heat dissipation path (i.e., heat convection via air). In fact, heat dissipation efficiency can be increased because heat from the coil is concentrated into a cooling fluid without distraction and the cooling fluid can fully utilize its capacity to dissipate heat from the coil in some embodiments. Thereby, according to some embodiments of the present disclosure, heat from the coil can efficiently be dissipated while keeping heat transmission to a pole piece at a minimum level.

In the context of this disclosure, a low thermal conductivity material may be defined as a material having thermal conductivity values in the range of 1-10 W·m⁻¹·K⁻¹ under standard measurement conditions. A high thermal conductivity material may be defined as a material having thermal conductivity values in the range of 20-2000 W·m⁻¹·K⁻¹ under standard measurement conditions.

Relative dimensions of components in drawings may be exaggerated for clarity. Within the following description of drawings, the same or like reference numbers refer to the same or like components or entities, and only the differences with respect to the individual embodiments are described. Other objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing scanning deflection systems and scanning deflection methods in systems utilizing electron beams (“e-beams”). Some scanning deflection systems may use electric fields to influence a charged particle beam. However, the disclosure is not so limited. Other types of charged particle beams may be similarly applied. For example, systems and methods may be applicable with optics, photons, muons, x-rays, ions, or any other particle carrying electrical charges. Deflection may be used to scan a beam over a surface in, for example, cathode ray tubes (CRTs), lithography machines, scanning charged-particle microscopes (SCPMs), or other analytical instruments. While some embodiments are discussed with reference to deflection systems that use electric field to influence a beam, deflection may also be achieved with magnetic fields, for example.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

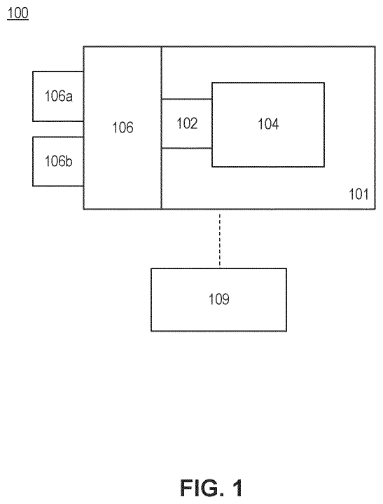

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

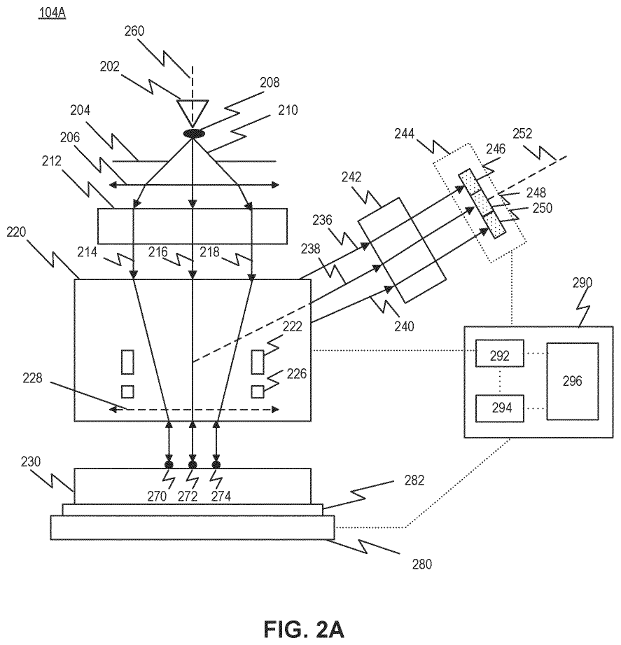

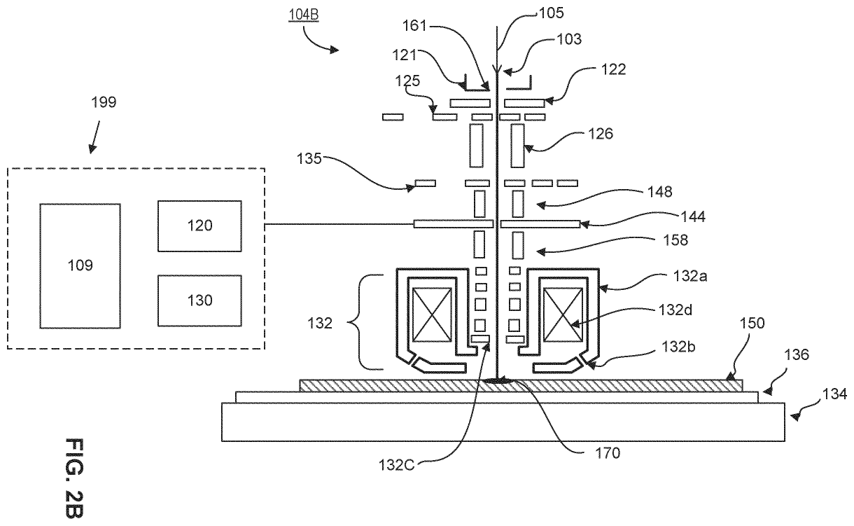

FIG. 2A illustrates a schematic diagram of an exemplary multi-beam beam tool 104A (also referred to herein as apparatus 104A) and an image processing system 290 that may be configured for use in EBI system 100 (FIG. 1), consistent with embodiments of the present disclosure.

Beam tool 104A comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104A. Secondary optical system 242 and charged-particle detection device 244 can be aligned with a secondary optical axis 252 of apparatus 104A.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2A, embodiments of the present disclosure are not so limited. For example, in some embodiments, the apparatus 104A may be configured to generate a first number of beamlets. In some embodiments, the first number of beamlets may be in a range from 1 to 1000. In some embodiments, the first number of beamlets may be in a range from 200-500. In an exemplary embodiment, an apparatus 104A may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104A through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2A). The quantity of BSEs and SEs may be more or fewer (or even the same) than the injected electrons of primary charged-particle beam 210.

Another example of a charged particle beam apparatus will now be discussed with reference to FIG. 2B. Beam tool 104B (also referred to herein as apparatus 104B) may be an example of beam tool 104 and may be similar to beam tool 104A shown in FIG. 2A. However, different from apparatus 104A, apparatus 104B may be a single-beam tool that uses only one primary electron beam to scan one location on the wafer at a time.

As shown in FIG. 2B, apparatus 104B includes a wafer holder 136 supported by motorized stage 134 to hold a wafer 150 to be inspected. Beam tool 104B includes an electron emitter, which may comprise a cathode 103, an anode 121, and a gun aperture 122. Beam tool 104B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector unit 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector unit 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of beam tool 104B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 104B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2B, discussed above, a beam separator 222 may be provided to direct secondary electron beams toward a detector placed off-axis. Beam separator 222 may be configured to divert secondary electron beams toward an electron detection device 244, as shown in FIG. 2A.

The images generated by SCPM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SCPM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

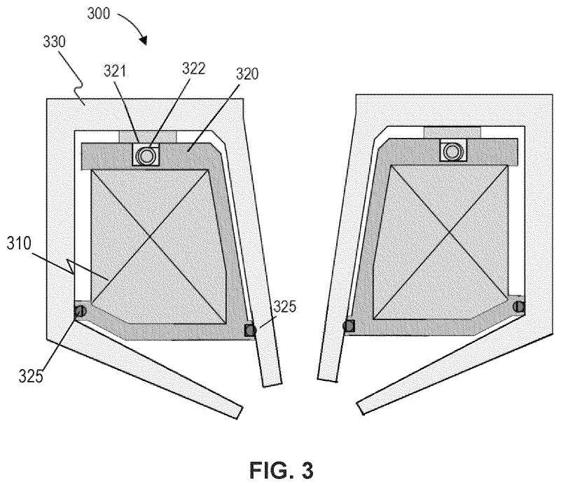

Reference is now made to FIG. 3, which is a cross-section view of a conventional magnetic lens assembly. As shown in FIG. 3, a magnetic lens assembly 300 may comprise a coil 310, a bobbin 320, and a pole piece 330. In FIG. 3, the longitudinal axis of magnetic lens assembly 300 may align with primary optical axis 301. Coil 310 can be an electromagnetic coil and be placed within bobbin 320. Bobbin 320 can comprise a cooling system that absorbs heat generated by coil 310. As shown in FIG. 3, bobbin 320 comprises a tube 322 as a cooling system. Tube 322 can be inlaid in a groove 321 formed in bobbin 320 and circulate a fluid that absorbs heat generated by coil 310. Tube 322 can be attached in groove 321 with a thermally conductive material such as epoxy. The fluid is supplied to tube 322 from outside of the system (e.g., from a fluid resource) and circulates bobbin 320 via tube 322 absorbing heat generated by coil 310, and the heated fluid is emitted out of bobbin 320.

In the conventional architecture, magnetic lens assembly 300 can utilize air as another heat dissipation medium from coil 310 in addition to a fluid. As shown in FIG. 3, magnetic lens assembly 300 comprises an O-ring 325 configured to seal air in a space embracing bobbin 320 containing coil 310. In FIG. 3, an air jacket is formed to embrace bobbin 320 and coil 310 by introducing pressurized air and sealing the air with O-ring 325. As shown in FIG. 3, coil 310 and bobbin 320 can be surrounded by air. In this conventional architecture, the air can be confined in a space between coil 310/bobbin 320 and pole piece 330 sealed by O-ring 325. In magnetic lens assembly 300, heat generated by coil 310 can also be dissipated via heat convection using the air sealed by O-ring 325 as a heat transmission medium. However, when heat is dissipated outside of coil 310 via heat convection, the heat from coil 310 can be transmitted to pole piece 330 and thus can still cause thermal expansion of pole piece 330 and deform a geometry of pole piece 330. As a result, magnetic lens assembly 300 still suffers from a beam placement accuracy error caused by a thermal expansion or deformation of pole piece 300. Therefore, a cooling mechanism that can minimize heat transmission to pole piece 330 while efficiently cooling down coil 310 is desired.

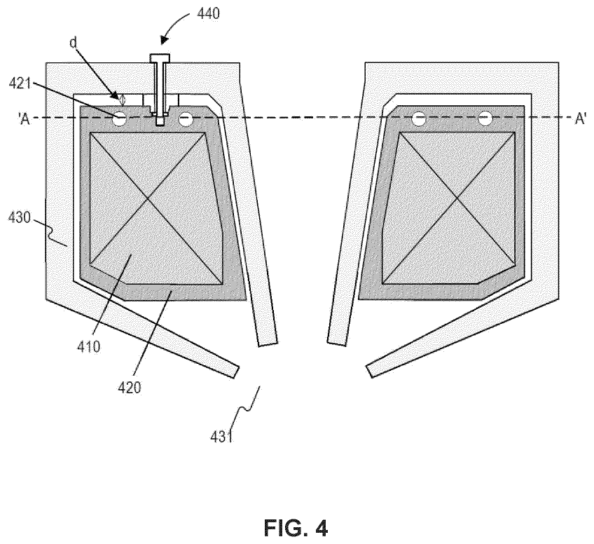

FIG. 4 is a cross-section view of an exemplary magnetic lens assembly, consistent with embodiments of the present disclosure. In some embodiments, a magnetic lens assembly 400 can be an objective lens (e.g., objective lens 228 of FIG. 2A) or an objective lens assembly (e.g., objective lens assembly 132 of FIG. 2B). As shown in FIG. 4, magnetic lens assembly 400 can comprise a coil 410, a housing 420, and a pole piece 430. In FIG. 4, the longitudinal axis of magnetic lens assembly 400 may align with a primary optical axis 401. In some embodiments, primary optical axis 401 can be a primary optical axis such as primary optical axis 260 of apparatus 104A in FIG. 2A or optical axis 105 in FIG. 2B.

In some embodiments, coil 410 can be an electromagnetic coil configured to adjust the focus of a single or multiple charged-particle beams. Coil 410 may comprise an electrical conductor, such as a wire in the shape of a coil, spiral, helix, etc. An electric current may be passed through coil 410 to produce a circular magnetic field around the conductor. In a coil configuration, the electrical conductor may be wound multiple times to increase the magnetic field density. Coil 410 may comprise an electrical conductor including, but not limited to, copper, aluminum, silver, etc. In some embodiments, the electrical conductor wire, such as copper wire, may be encapsulated with an insulating material. Due to the large amount of heat generated by passing electrical current through coil 410, a thermal gap filler material may be applied between each layer of coils. The thermal gap filler material may comprise thermal gap filler gels, putty, or pads having a thermal conductivity of 1 W·m⁻¹·K⁻¹ or higher, to dissipate the local heat and electrical resistance of 5×10¹² ohms or higher to provide electrical insulation between two layers of conductor coil. It should be appreciated that other suitable thermal gap filler materials may be used as well.

In some embodiments, housing 420 may be configured to house coil 410. As shown in FIG. 4, housing 420 can be configured to house entire coil 410. In some embodiments, housing 420 can be configured to house at least a portion of coil 410. In some embodiments, housing 420 can be configured to include a bobbin around which coil 410 is wound.

According to some embodiments of the present disclosure, housing 420 may have a channel 421 or a plurality of channels 421. A channel, as referred to herein, may be a path through which a fluid may pass or circulate, and may include more than one channel. In some embodiments, housing 420 comprises a plurality of channels 421 through which a fluid may circulate. The fluid may comprise a cooling fluid including, but not limited to, a coolant, a cooling liquid, water, gas, compressed gas, or mixtures thereof. It should be appreciated that channel, plurality of channels, channels and cooling channels may be interchangeably used herein.

In some embodiments, housing 420 having cooling channels 421 may comprise a single material having thermal conductivity in the range of 20-2000 W·m⁻¹·K⁻¹ under standard measurement conditions, for example, materials including but not limited to aluminum, titanium, copper, graphite, aluminum nitride, aluminum carbide, metal alloys, metal-ceramic composites, etc. In some embodiments, housing 420 having cooling channels 421 may comprise more than one material having different thermal conductivity and machinability, for example, a portion of housing 420 may comprise aluminum and cooling channels 421 may comprise titanium. Other combinations may be possible as well.

In some embodiments, housing 420 having a plurality of channels 421 may comprise a monolithic structure. A monolithic structure, as referred to herein, may be defined as a structure made from a single piece of material. For example, monolithic structures may be formed either by a subtractive manufacturing process or an additive manufacturing process. Subtractive manufacturing process is a process by which three-dimensional (3D) objects are created by successively cutting material away from a single block of material, either manually or using a computer numerical control (CNC) machine. Additive manufacturing process is a process of creating three-dimensional components by depositing overlapping layers of material under the guided control of a computer, for example, 3D printing. In some embodiments, housing 420 having channels 421 may comprise an additively manufactured monolithic structure. Additively manufactured housing 420 having channels 421 may comprise a single metal, such as, for example, aluminum or titanium.

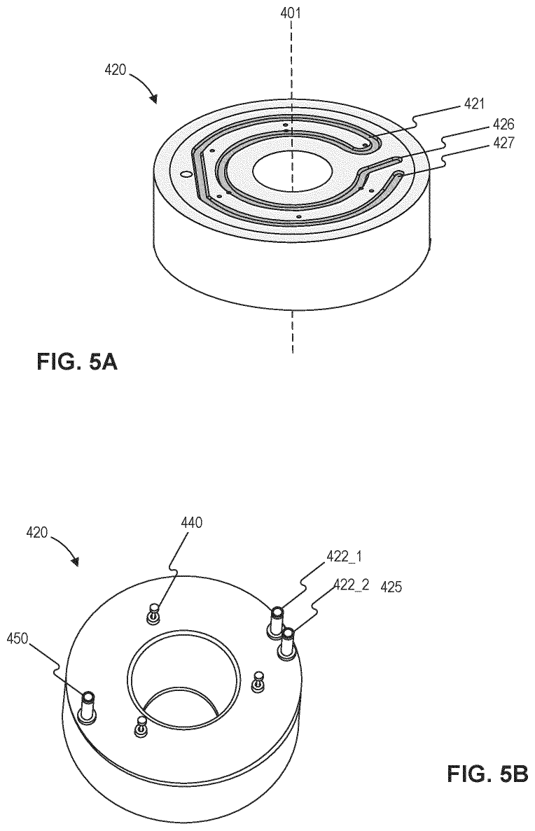

In some embodiments, channels 421 may be disposed on the outer surface of housing 420 and may be arranged vertically, or horizontally, or circumferentially around housing 420. In some embodiments, channels 421 may be disposed within housing 420 as shown in FIG. 4, and may be arranged vertically, or horizontally, or circumferentially within housing 420. Other channel layouts and configurations may be suitably used. FIG. 5A is a schematic diagram illustrating an exemplary fluid channel formed in housing 420 of magnetic lens assembly 400 of FIG. 4, consistent with embodiments of the present disclosure. FIG. 5A shows a cross-section of housing 420 along a cutting-plane line A-A′ in FIG. 4. In FIG. 5A, channel 421 is deployed to circulate a fluid close to coil 410 beneath channel 421. While FIG. 4 and FIG. 5A illustrate channel 421 being deployed on a top side of coil 410, it will be appreciated that channel 421 can be formed along any path vertically, or horizontally, or circumferentially in housing 420.

As shown in FIG. 5A, channel 421 can include an inlet terminal 426 and an outlet terminal 427. In some embodiments, inlet terminal 426 can be configured to be coupled to an input channel that supplies a fluid into channel 421, and outlet terminal 427 is configured to be coupled to an output channel that dispense the circulated fluid out of channel 421. A fluid, as referred to herein, may comprise, among others, a liquid, a coolant, a cooling liquid, a gas, a compressed gas, or mixtures thereof. The fluid may be configured to absorb heat generated by passing large electric current through electromagnetic coil 410. The fluid may circulate through channel 421 before being discharged out of the system via outlet terminal 427.

An input channel 422_1 and an output channel 422_2 are illustrated in FIG. 5B, which a schematic diagram illustrating housing 420 of magnetic lens assembly 400 of FIG. 4, consistent with embodiments of the present disclosure. In some embodiments, input channel 422_1 is coupled to an inlet terminal of a channel (e.g., inlet terminal 426 of channel 421) inside of housing 420. In some embodiments, input channel 422_1 extends to the outside of housing 420 to receive a fluid from a fluid supplier (not illustrated). In some embodiments, output channel 422_2 coupled to an outlet terminal of a channel (e.g., outlet terminal 427 of channel 421) inside of housing 420. In some embodiments, output channel 422_2 extends to the outside of housing 420 to emit a circulated fluid out of housing 420.

In some embodiments, channel 421 may comprise a single loop around housing 420. In some embodiments, channel 421 may comprise multiple loops around housing 420, based on the application and system cooling requirements. In some embodiments, channel 421 may comprise one or more input channels and a single output channel. For example, an additional input channel may be used. In some embodiments, channel 421 may comprise a single input channel and multiple output channels. Other combinations of numbers and configurations of input channels and output channels may be suitably designed and employed.

In some embodiments, channel 421 may comprise an enclosed path, for example, a channel having a circular or an elliptical cross-section, and a wall thickness. The shape of the cross-section and the area of the cross-section may be determined based on the application, space availability, material compatibility, or cooling requirements of the system. Channel 421 may comprise uniform or non-uniform wall thicknesses. It should be appreciated that the size, shape, cross-section, area, total volume and other relevant dimensions of channel 421 may be determined and designed, as needed.

Referring back to FIG. 4, magnetic lens assembly 400 can further comprise pole piece 430. In some embodiments, pole piece 430 can be configured to guide a magnetic field generated by coil 410. As shown in FIG. 4, pole piece 430 can be configured to be around housing 420 containing coil 410 therein. In some embodiments, pole piece 430 can also be configured to have a gap 431 for guiding a magnetic field as shown in FIG. 4. In some embodiments, pole piece 430 can comprise a ferromagnetic material including, but not limited to, cobalt, nickel, iron, chromium dioxide, or alloys thereof. Ferromagnetic materials, as described herein, may refer to materials that have a large, positive susceptibility to an external magnetic field. Ferromagnetic materials exhibit a strong attraction to magnetic fields and are able to retain their magnetic properties after the external field has been removed. In some embodiments, pole piece 430 may comprise a material having low thermal conductivity including, but not limited to, ceramic materials such as cerium oxide, silica, fused silica, quartz, zirconium dioxide, etc. In some embodiments, pole piece 430 may comprise a material coated with a low thermal conductivity material, such as, for example, cerium oxide.

According to some embodiments of the present disclosure, pole piece 430 can be thermally isolated from housing 420 such that there is a gap between housing 420 and pole piece 430. In FIG. 4, it is illustrated that an inner surface of pole piece 430, which faces housing 420, is spaced apart from an outer surface of housing 420 by a distance d. In some embodiments, pole piece 430 is isolated from housing 420 on all sides. In some embodiments, distance d between housing 420 and pole piece 430 can vary pending on a position on the outer surface of housing 420 or the inner surface of pole piece 430. According to some embodiments of the present disclosure, a gap between housing 420 and pole piece 430 can be maintained under a vacuum pressure during operation of magnetic lens assembly 400. In some embodiments, the vacuum pressure can be an ultra-high vacuum (UHV) pressure. In some embodiments, the vacuum pressure can be in a range between 10 e-11 Torr and 10 e-6 Torr. In some embodiments, magnetic lens assembly 400 can be placed in a vacuum chamber (not shown) that provides a vacuum pressure (e.g., UHV) and thereby a gap between housing 420 and pole piece 430 can be maintained under the vacuum pressure provided by the vacuum chamber. In some embodiments, the vacuum chamber can be evacuated of air or gases using a vacuum pump. In some embodiments, a vacuum chamber existing within an inspection system can be utilized as the vacuum chamber for providing the UHV pressure to magnetic lens assembly 400. For example, the vacuum chamber can be main chamber 101 of EBI system 100 shown in FIG. 1.

As the gap between housing 420 and pole piece 430 is in vacuum condition, heat transmission from coil 410 to pole piece 430 via heat convection can be minimized. Thereby, the amount of heat transferred to pole piece 430 from coil 410 can be reduced. In some embodiments, a minimum distance (e.g., distance d) between housing 420 and pole piece 430 can be utilized to thermally isolate pole piece 430 as thermal isolation is a function of a vacuum level instead of a distance between housing 420 and pole piece 430. That is, as a vacuum pressure gets higher, better thermal isolation can be achieved regardless of an actual distance between housing 420 and pole piece 430.

While magnetic lens assembly 400 of FIG. 4 eliminates one heat dissipation path (e.g., heat convection via air) from coil 410, it will be appreciated that heat dissipation efficiency from coil 410 may not be affected by the loss of the heat dissipation path. As heat dissipation from coil 410 can be concentrated into a cooling fluid circulating via channel 421, heat dissipation efficiency may not be degraded by the loss of the heat dissipation path via air. In some embodiments, heat dissipation efficiency can be increased because heat from coil 310 is concentrated into a cooling fluid without distraction and the cooling fluid can fully utilize its capacity to dissipate heat from coil 410. Thereby, according to some embodiments of the present disclosure, heat from coil 410 can more efficiently be dissipated while keeping heat transmission to pole piece 430 at a minimum level, which can minimize thermal expansion or dimension deformation of pole piece 430.

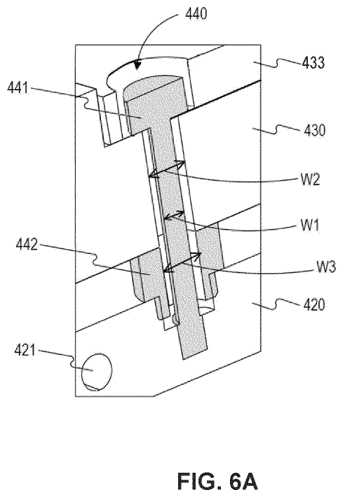

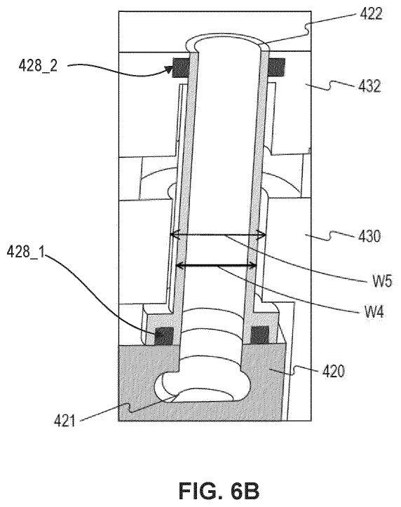

Referring back to FIG. 4, magnetic lens assembly 400 can further comprise a coupling structure 440 that couples housing 420 with pole piece 430, consistent with some embodiments of the present disclosure. Coupling structure 440 can be configured to place housing 420 in the inner space of pole piece 430 while isolating pole piece 430 from housing 420 as shown in FIG. 4. FIG. 6A is a schematic diagram illustrating exemplary coupling structure 440 coupling housing 420 to pole piece 430, consistent with embodiments of the present disclosure. As shown in FIG. 6A, coupling structure 440 can comprise a screw 441 that is configured to fasten housing 420 relative to pole piece 430. According to some embodiments of the present disclosure, housing 420 can be coupled to pole piece 430 using coupling structure 440 in a way that can minimize heat transmission to pole piece 430. In some embodiments, a head portion of screw 441 is abutted directly or indirectly against an outer surface of pole piece 430 and a tip portion of screw 441 is placed into a recess formed in housing 420. In some embodiments, screw 441 can be configured such that a side surface of the head portion is not in contact with structure 433 surrounding the head portion while a bottom surface of the head portion of screw 441 is abutted against the outer surface of pole piece 430 as shown in FIG. 6A. The recess can be configured to accept the tip portion of screw 44 as shown in FIG. 6A. In some embodiments, screw 441 is configured to be inserted into a hole formed in pole piece 430 when fastening housing 420 to pole piece 430. In some embodiments, screw 441 can be configured to have a width W1 that is narrower than a width W2 of the hole formed in pole piece 430 such that screw 441 is not in contact with an inner wall forming the hole in pole piece 430 when installed. Because screw 441 does not contact the inner wall of pole piece 430, heat transmission from coil 410 to pole piece 430 through screw 410 can be minimized when fastening housing 420 relative to pole piece 430.

In some embodiments, coupling structure 440 can further comprise a standoff 442 configured to maintain a distance between housing 420 and pole piece 430. As shown in FIG. 6A, standoff 442 can also be configured to allow screw 441 to be inserted into a hole formed in standoff 442. In some embodiments, a hole width W3 in standoff 442 can also be wider than width W1 of screw 441 such that screw 441 is not in contact with an inner wall forming the hole in standoff 442 when installed. Thereby, heat transfer from coil 410 to pole piece 430 can be minimized through screw 441 and standoff 442. In some embodiments, coupling structure 440 can comprise a material having low thermal conductivity. In some embodiments, the material having low thermal conductivity can comprise polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, steatite, etc. In some embodiments, screw 441 that fastens housing 420 to pole piece can have a material having high mechanical strength. In some embodiments, screw 441 can comprise stainless steel 303, stainless steel 304, stainless steel 316, stainless steel 316L, titanium grade 2, titanium grade 5, aluminum, brass, bronze, carbon fiber, ceramic, fiberglass, iron, lead, nickel, nickel alloy, plastic, etc. In some embodiments, standoff 442 can comprise a low thermal conductivity material such as polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, steatite, etc. In some embodiments, magnetic lens assembly 400 can have one or more coupling structure 440 to fasten housing 420 relative to pole piece 430. While three coupling structures 440 installed in housing 420 are illustrated in FIG. 5, it will be appreciated that any number of coupling structures 440 can be utilized. While coupling structure 440 has been discussed referring to FIG. 6A, it will be appreciated that any configuration that can similarly minimize heat transmission from coil 410 to pole piece 430 can be utilized.

Similarly, other components of magnetic lens assembly 400 can be configured to minimize heat transmission to pole piece 430. For example, a fluid input channel or output channel can be installed to minimize heat transmission to pole piece 430. FIG. 6B is a schematic diagram illustrating an exemplary fluid channel in magnetic lens assembly 400 of FIG. 4, consistent with embodiments of the present disclosure. According to some embodiments of the present disclosure, fluid channel 422 can be an input channel (e.g., input channel 422_1) that is configured to supply a fluid to channel 421 or can be an output channel (e.g., output channel 422_2) that is configured to discharge a fluid out of channel 421. As shown in FIG. 6B, fluid channel 422 can be configured as a fluid tube in some embodiments. Fluid channel 422 can be connected to an inlet terminal of channel 421 (e.g., inlet terminal 426 of FIG. 5A) or an outlet terminal of channel 421 (e.g., outlet terminal 426 of FIG. 5A). In some embodiments, O-ring 428 can be utilized when connecting fluid channel 422 to channel 421 of magnetic lens assembly 400 to prevent leakage of fluid. O-ring 428 can be placed at an interface of two contacting surfaces. For example, FIG. 6B illustrates first O-ring 428_1 positioned at an interface between fluid channel 422 and housing 420 and a second O-ring 428_2 positioned at an interface between fluid channel 422 and a structure 432 placed in the outer side of pole piece 430 as an example. According to some embodiments of the present disclosure, fluid channel 422 can be coupled to channel 421 in a way that can minimize heat transmission to pole piece 430. In some embodiments, fluid channel 422 is configured to penetrate through a hole formed in pole piece 430. In some embodiments, fluid channel 422 can be configured to have a width W4 that is narrower than a width W5 of the hole formed in pole piece 430 such that fluid channel 422 is not in contact with an inner wall forming the hole in pole piece 430 when installed. Because fluid channel 422 does not contact the inner wall of pole piece 430, heat transmission from coil 410 to pole piece 430 through fluid channel 422 can be minimized. In some embodiments, fluid channel 422 can be installed such that fluid channel 422 does not have a direct contact with pole piece 430 as shown in FIG. 6B. In FIG. 6B, it is illustrated that fluid channel 422 is not fixed to pole piece 430 and only passes through pole piece 430. As shown in FIG. 6B, fluid channel 422 can be fixed to structure 432 placed in the outer side of pole piece 430 as an example. In some embodiments, fluid channel 422 can comprise a low thermal conductivity material such as Titanium grade 5.

In some embodiments, magnetic lens assembly 400 can have two fluid channels 422_1 and 422_2 connected to channel 421 as shown in FIG. 5B. For example, first fluid channel 422_1 can be connected to inlet terminal 426 of channel 421 as shown in FIG. 5A, and second fluid channel 422_2 can be connected to outlet terminal 427 of channel 421 as shown in FIG. 5A. While two fluid channels 422_1 and 422_2 installed in housing 420 are illustrated in FIG. 5B, it will be appreciated that any number of fluid channel 422 can be utilized. While fluid channel 422 has been discussed referring to FIG. 6B, it will be appreciated that any configuration that can similarly minimize heat transmission from coil 410 to pole piece 430 can be utilized.

Referring back to FIG. 5B, magnetic lens assembly 400 can further comprise a wire tube 450 that provide wires for coil 310, consistent with some embodiments of the present disclosure. In some embodiments, wire tube 450 can be configured to provide wires for coil 310 from the outside of the system. In some embodiments, wire tube 450 can also be configured to minimize heat transmission to pole piece 430 similar to fluid channel 422 illustrated in FIG. 6A. For example, wire tube 450 can be configured as a tube within which a path for wires is provided. In some embodiments, wire tube 450 can be installed such that wire tube 450 is not in direct contact with pole piece 430, which is similar to the configuration of fluid channel 422 in FIG. 6B.

According to some embodiments of the present disclosure, magnetic lens assembly 400 can further comprise a thermal insulation layer (not shown) between housing 420 and pole piece 430. In some embodiments, a thermal insulation layer can be configured to further reduce heat transmission to pole piece 430. In some embodiments, a thermal insulation layer can be configured to reduce heat transmission via radiation caused by a temperature difference between two objects such as between housing 420 and pole piece 430. In some embodiments, a thermal insulation layer can be configured to block infrared energy transmission to pole piece 430 from a heat source, i.e., coil 410. In some embodiments, the thermal insulation layer can be a multilayer insulator. For example, the thermal insulation layer can comprise an aluminum layer coated on one side of the thermal insulation layer. The thermal insulation layer can comprise a fiber glass layer on another side of the thermal insulation layer. In some embodiments, a thermal insulation layer can be formed on either side of an outer surface of housing 420 or an inner surface of pole piece 430.

The embodiments may further be described using the following clauses:
1. A magnetic lens assembly comprising:
a coil;
a housing containing the coil; and
a pole piece that is isolated from the housing such that there is a gap between the housing and the pole piece,
wherein the magnetic lens assembly is configured to have a vacuum pressure in the gap.
2. The magnetic lens assembly of clause 1, wherein the vacuum pressure is an ultra-high vacuum pressure.
3. The magnetic lens assembly of clause 1 or 2, wherein the housing is coupled to the pole piece via a low thermal conductivity material.
4. The magnetic lens assembly of clause 3, wherein the low thermal conductivity material comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.
5. The magnetic lens assembly of any one of clauses 1-4, wherein the housing is coupled to the pole piece via a screw and a standoff positioned between the housing and the pole piece.
6. The magnetic lens assembly of clause 5, wherein the standoff comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.
7. The magnetic lens assembly of clause 5, wherein the screw comprises stainless steel 303, stainless steel 304, stainless steel 316, stainless steel 316L, titanium grade 2, titanium grade 5, aluminum, brass, bronze, carbon fiber, ceramic, fiberglass, iron, lead, nickel, nickel alloy, or plastic.
8. The magnetic lens assembly of any one of clauses 5-7, wherein the screw has a portion that is inserted into a hole formed in the housing, the portion of the screw having a narrower width than a width of the hole formed in the housing.
9. The magnetic lens assembly of any one of clauses 1-8, further comprising a thermal insulation layer between the housing and the pole piece.
10. The magnetic lens assembly of clause 9, wherein the thermal insulation layer comprises a layer having fiber glass or aluminum.
11. The magnetic lens assembly of any one of clauses 1-10, wherein the housing further comprises:
an inlet terminal configured to receive a fluid;
a channel formed in the housing and configured to circulate the fluid received by the inlet terminal; and
an outlet terminal configured to discharge the fluid out of the channel.
12. The magnetic lens assembly of clause 11, wherein the housing further comprises an input tube that is configured to supply the fluid to the channel via the inlet terminal, the input tube being not in contact with the pole piece when installed.
13. The magnetic lens assembly of any one of clauses 1-12, wherein the housing is enclosed in a vacuum environment provided in the pole piece.
14. A charged-particle beam inspection apparatus comprising:
a charged-particle beam source configured to generate a primary charged-particle beam for sample scanning; and
an objective lens assembly configured to influence the charged particle beam, the objective lens assembly comprising:
a coil;
a housing containing the coil; and
a pole piece that is isolated from the housing such that there is a gap between the housing and the pole piece,
wherein the objective lens assembly is configured to have a vacuum pressure in the gap.
15. The charged-particle beam inspection apparatus of clause 14, wherein the vacuum pressure is an ultra-high vacuum pressure.
16. The charged-particle beam inspection apparatus of clause 14 or 15, wherein the housing is coupled to the pole piece via a low thermal conductivity material.
17. The charged-particle beam inspection apparatus of clause 16, wherein the low thermal conductivity material comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.
18. The charged-particle beam inspection apparatus of any one of clauses 14-17, wherein the housing is coupled to the pole piece via a screw and a standoff positioned between the housing and the pole piece.
19. The charged-particle beam inspection apparatus of clause 18, wherein the standoff comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.
20. The charged-particle beam inspection apparatus of clause 19, wherein the screw comprises stainless steel 303, stainless steel 304, stainless steel 316, stainless steel 316L, titanium grade 2, titanium grade 5, aluminum, brass, bronze, carbon fiber, ceramic, fiberglass, iron, lead, nickel, nickel alloy, or plastic.
21. The charged-particle beam inspection apparatus of any one of clauses 18-20, wherein the screw has a portion that is inserted into a hole formed in the housing, the portion of the screw having a narrower width than a width of the hole formed in the housing.
22. The charged-particle beam inspection apparatus of any one of clauses 14-21, wherein the objective lens assembly further comprises a thermal insulation layer between the housing and the pole piece.
23. The charged-particle beam inspection apparatus of clause 22, wherein the thermal insulation layer comprises a layer having fiber glass or aluminum.
24. The charged-particle beam inspection apparatus of any one of clauses 14-23, wherein the housing further comprises:
an inlet terminal configured to receive a fluid;
a channel formed in the housing and configured to circulate the fluid received by the inlet terminal; and
an outlet terminal configured to discharge the fluid out of the channel.
25. The charged-particle beam inspection apparatus of clause 24, wherein the housing further comprises an input tube that is configured to supply the fluid to the channel via the inlet terminal, the input tube being not in contact with the pole piece when installed.
26. The magnetic lens assembly of any one of clauses 14-25, wherein the housing is enclosed in a vacuum environment provided in the pole piece.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments will be apparent to those skilled in the art from consideration of the specification and practice of the technology disclosed herein. It is intended that the specification and examples be considered as exemplary only, with a true scope and spirit of the invention being indicated by the following claims.

1. A magnetic lens assembly comprising:
a coil;
a housing containing the coil; and
a pole piece that is isolated from the housing such that there is a gap between the housing and the pole piece,
wherein the magnetic lens assembly is configured to have a vacuum pressure in the gap.

2. The magnetic lens assembly of claim 1, wherein the vacuum pressure is an ultra-high vacuum pressure.

3. The magnetic lens assembly of claim 1, wherein the housing is coupled to the pole piece via a low thermal conductivity material.

4. The magnetic lens assembly of claim 3, wherein the low thermal conductivity material comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.

5. The magnetic lens assembly of claim 1, wherein the housing is coupled to the pole piece via a screw and a standoff positioned between the housing and the pole piece.

6. The magnetic lens assembly of claim 5, wherein the standoff comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.

7. The magnetic lens assembly of claim 5, wherein the screw comprises stainless steel 303, stainless steel 304, stainless steel 316, stainless steel 316L, titanium grade 2, titanium grade 5, aluminum, brass, bronze, carbon fiber, ceramic, fiberglass, iron, lead, nickel, nickel alloy, or plastic.

8. The magnetic lens assembly of claim 5, wherein the screw has a portion that is inserted into a hole formed in the housing, the portion of the screw having a narrower width than a width of the hole formed in the housing.

9. The magnetic lens assembly of claim 1, further comprising a thermal insulation layer between the housing and the pole piece.

10. The magnetic lens assembly of claim 9, wherein the thermal insulation layer comprises a layer having fiber glass or aluminum.

11. The magnetic lens assembly of claim 1, wherein the housing further comprises:
an inlet terminal configured to receive a fluid;
a channel formed in the housing and configured to circulate the fluid received by the inlet terminal; and
an outlet terminal configured to discharge the fluid out of the channel.

12. The magnetic lens assembly of claim 11, wherein the housing further comprises an input tube that is configured to supply the fluid to the channel via the inlet terminal, the input tube being not in contact with the pole piece when installed.

13. The magnetic lens assembly of claim 1, wherein the housing is enclosed in a vacuum environment provided in the pole piece.

14. A charged-particle beam inspection apparatus comprising:
a charged-particle beam source configured to generate a primary charged-particle beam for sample scanning; and
an objective lens assembly configured to influence the charged particle beam, the objective lens assembly comprising:
a coil;
a housing containing the coil; and
a pole piece that is isolated from the housing such that there is a gap between the housing and the pole piece,
wherein the objective lens assembly is configured to have a vacuum pressure in the gap.

15. The charged-particle beam inspection apparatus of claim 14, wherein the vacuum pressure is an ultra-high vacuum pressure.

16. The charged-particle beam inspection apparatus of claim 14, wherein the housing is coupled to the pole piece via a low thermal conductivity material.

17. The charged-particle beam inspection apparatus of claim 16, wherein the low thermal conductivity material comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.

18. The charged-particle beam inspection apparatus of claim 14, wherein the housing is coupled to the pole piece via a screw and a standoff positioned between the housing and the pole piece.

19. The charged-particle beam inspection apparatus of claim 18, wherein the standoff comprises polystyrene, polyethylene terephthalate (PET), polyether ether ketone (PEEK), fiberglass, paper, polycarbonate, polyester, polyethylene low density, polyethylene high density, polypropylene, polyurethane, polytetrafluoroethylene (PTFE), polyvinylchloride (PVC), glass, silicon, Styrofoam, or steatite.

20. The charged-particle beam inspection apparatus of claim 19, wherein the screw comprises stainless steel 303, stainless steel 304, stainless steel 316, stainless steel 316L, titanium grade 2, titanium grade 5, aluminum, brass, bronze, carbon fiber, ceramic, fiberglass, iron, lead, nickel, nickel alloy, or plastic.
